(19) United States
(12) Patent Application Publication
(10) Pub. No.: US 2012/0285521 A1
(43) Pub. Date: Nov. 15, 2012

(54) SILICON/ORGANIC HETEROJUNCTION (SOH) SOLAR CELL AND ROLL-TO-ROLL FABRICATION PROCESS FOR MAKING SAME

(75) Inventors: Yifei Huang, Whitestone, NY (US); Sushobhan Avasthi, Princeton, NJ (US); James C. Sturm, Princeton, NJ (US); Ken Nagamatsu, Princeton, NJ (US)

(73) Assignee: THE TRUSTEES OF PRINCETON UNIVERSITY, Princeton, NJ (US)

(21) Appl. No.: 13/467,515

(22) Filed: May 9, 2012

Related U.S. Application Data
(60) Provisional application No. 61/484,128, filed on May 9, 2011.

(51) Int. Cl. H01L 51/44; H01L 51/48

(52) U.S. Cl. 136/255; 438/82; 257/E51.026

(57) ABSTRACT

A photovoltaic device and method of making a photovoltaic device are disclosed. The method includes laminating an organic layer onto an inorganic semiconductor layer. A first electrical contact is electrically coupled to the organic layer and a second electrical contact is coupled to the inorganic semiconductor layer. The inorganic semiconductor layer may include a second organic layer. At least one of the organic layer and the second organic layer may form a heterojunction with the inorganic semiconductor layer. The organic layer may further comprise a metal layer. At least one of the organic layer, the inorganic semiconductor layer and the metal layer may be patterned.

### CROSS-REFERENCE TO PRIOR FILED APPLICATIONS

This application claims priority to earlier filed provisional applications 61/484,128 which was filed on May 9, 2011, incorporated herein in its entirety.

### FIELD OF INVENTION

This invention relates to the field of photovoltaic devices more specifically to the formation and use of heterojunctions in such devices.

### BACKGROUND

It has long been desirable to make and use photovoltaic devices. Such devices are useful for detecting electromagnetic radiation, converting electromagnetic radiation to electrical energy, converting electrical energy into light energy and/or other desirable uses.

Photovoltaic devices are sensitive to electromagnetic radiation. In the presence of electromagnetic radiation, photovoltaic devices convert the electromagnetic radiation energy into electrical energy. A solar cell is an example of a photovoltaic device.

Some more efficient forms of photovoltaic devices are constructed from crystalline silicon. However, manufacture of crystalline silicon photovoltaic devices is expensive. Other photovoltaic devices may be manufactured with non-silicon materials for less expense. However, these photovoltaic devices are less efficient in the conversion of electromagnetic radiation into electrical energy. U.S. Pat. No. 7,868,405 B2 issued on Jan. 11, 2011 to Brabec et al. is an example of using organic materials to produce photovoltaic devices from organic material with the aim of reducing manufacturing costs. Brabec discloses an organic heterojunction and fails to produce the efficiency of conversion of electromagnetic radiation into electrical energy observed in state of the art crystalline silicon devices.

There exists a need for photovoltaic devices using heterojunctions and associated manufacturing methods that reduce manufacturing costs and provide the ability to improve efficiency and performance of the photovoltaic devices.

### SUMMARY OF THE INVENTION

A method of making a photovoltaic device is disclosed. The method includes laminating an organic layer onto an inorganic semiconductor layer. A first electrical contact is electrically coupled to the organic layer and a second electrical contact is coupled to the inorganic semiconductor layer. The inorganic semiconductor layer may include a second organic layer. At least one of the organic layer and the second organic layer may form a heterojunction with the inorganic semiconductor layer. The organic layer may further comprise a metal layer. At least one of the organic layer, the inorganic semiconductor layer and the metal layer may be patterned. The inorganic semiconductor layer may further comprise a second organic layer.

The metal layer may include a first tab that overhangs at least one edge of the inorganic semiconductor layer. A second photovoltaic device may be provided. The second photovoltaic device may have a second metal layer including a second tab that overhangs at least one edge of a second inorganic semiconductor layer. The first tab may be electrically connected (directly or indirectly) to the second tab.

Another method of making a photovoltaic device is also disclosed. The method includes providing an inorganic semiconductor layer having at least one of a PN junction and a heterojunction. A metal layer is laminated onto the inorganic semiconductor layer to form an electrical contact. The inorganic semiconductor layer may further comprise an organic layer. At least one of the inorganic semiconductor layer and the metal layer may be patterned. The method of claim may also include providing a second inorganic semiconductor layer having at least one of a PN junction and a heterojunction, wherein the metal layer is laminated onto the first and second inorganic semiconductor layers to form the electrical contact.

The metal layer may comprise a first tab that overhangs at least one edge of the inorganic semiconductor layer. The method may also include providing a second photovoltaic device having a second metal layer including a second tab that overhangs at least one edge of a second inorganic semiconductor layer. The first tab may be electrically coupled (directly or indirectly) to the second tab.

A photovoltaic device is disclosed. The photovoltaic device includes an inorganic semiconductor layer having at least one of a PN junction and a heterojunction. The photovoltaic device also includes a metal layer laminated to the inorganic semiconductor layer to form an electrical contact, the metal layer being formed with a first tab that overhangs at least one edge of the inorganic semiconductor layer. The inorganic semiconductor layer may further comprise an organic layer. At least one of the organic layer and the inorganic semiconductor layer may be patterned. The device may further include a conductive compound disposed between the first tab and the second tab. The photovoltaic device may further include a second photovoltaic device having a second metal layer including a second tab that overhangs at least one edge of a second inorganic semiconductor layer, and an electrical connection coupling the first tab to the second tab.

Another photovoltaic device is also disclosed. The device includes a first inorganic semiconductor layer having at least one of a first PN junction and a first heterojunction. The device also includes a second semiconductor layer having at least one of a second PN junction and a second heterojunction. The device also includes a metal layer laminated to the first and second inorganic semiconductor layers to form an electrical contact. At least one of the first and second semiconductor layers may further comprise an organic layer. The metal layer may further comprise an organic layer. At least one of the metal layer and the first and second inorganic semiconductor layers may be patterned.

### BRIEF DESCRIPTION OF THE FIGURES

FIGS. 1a and 1b are block diagrams comparing a Si/organic heterojunction and a conventional p-n-n+ junction;

FIG. 2a is block diagram showing the structure of a Si/P3HT heterojunction solar cell;

FIG. 2b is a graph showing the current-voltage characteristic of our “one-sided” Si/organic heterojunction solar cell (lower curve) compared to a device without PEDOT/P3HT stack (upper curve) under AM1.5 illumination;

FIG. 3a is a block diagram showing a spray coating roll to roll process including contact printing/lift-off patterning of metallization films;

FIG. 3b is a block diagram showing a spray coating roll to roll process including spray-coating of organic on an inorganic semiconductor layer, e.g., a silicon wafer, and metallization films, lamination of the three components to form the SOH cell, and encapsulation of the module with environmental barrier films;

FIG. 4a is a block diagram showing lamination of an organic coating on the surface of a patterned metallization film (top metallization film shown, the process may be the same for the bottom metallization film);

FIG. 4b is a block diagram showing lamination of organic films the surface of inorganic semiconductor layer, e.g., silicon, to form silicon-organic heterojunctions;

FIG. 4c is a block diagram showing lamination of the top and bottom metallization on the SOHs to form the completed SOH solar cell, and the deposition of environmental barriers on the module;

FIG. 5a is a block diagram showing lamination of organic(s) on an inorganic semiconductor layer;

FIG. 5b is a block diagram showing lamination of organic(s) on an organic coated inorganic semiconductor layer;

FIG. 6a is a block diagram showing lamination of a metal(s)/organic(s) stack on an inorganic semiconductor layer;

FIG. 6b is a block diagram showing lamination of a metal(s)/organic(s) stack on an organic(s)-coated inorganic semiconductor layer;

FIG. 7a is a block diagram showing lamination of a metal(s) on an inorganic semiconductor layer;

FIG. 7b is a block diagram showing lamination of a metal(s) on an organic(s)-coated inorganic semiconductor layer;

FIG. 8a is a block diagram showing lamination of metal(s) layers on solar cell, with a metal ledge that extends outside the device dimensions;

FIG. 8b is a block diagram showing lamination of metal(s)/organic(s) layer stack on solar cell, with a metal ledge that extends outside the device dimensions;

FIG. 9a is a block diagram showing lamination of two solar cells with metal ledges to form series connections;

FIG. 9b is a block diagram showing lamination of two solar cells with metal ledges to form series connections with an intermediate metal layer;

FIGS. 10a and 10b are block diagrams showing lamination of two solar cells with metal ledges to form parallel connections;

FIGS. 11a and 11b are block diagrams showing lamination of two solar cells with metal/organic layer to form parallel connections;

FIGS. 12a-12c are block diagrams showing transfer printing of a layer using a removable backing layer;

FIGS. 13a-13c are block diagrams showing transfer printing of a patterned metal/organic layer using a removable backing layer;

FIGS. 14a-14c are block diagrams showing transfer printing of a patterned metal/organic layer using a removable backing layer; and

FIG. 15 is a graph showing experimental results from transfer printing of a metal layer; a conventionally fabricated evaporated solar cell is also shown for comparison.

### DETAILED DESCRIPTION OF THE INVENTION

### Definitions

“homojunction” as used herein is a p-n junction made out of the same material.

“heterojunction” as used herein is an interface between materials with different electronic band structures.

“carrier blocking layer” as used herein refers to either an electron blocking layer, a hole blocking layer or a layer which blocks both electrons and holes.

“electron-blocking layer” as used herein is a material that allows the through transport of holes and prevents the through transport of electrons to and from silicon. This is may be achieved with an approximate alignment of “highest occupied molecular orbital” (HOMO)/valence-band edge (Ev) of the material with the valence-band edge (Ev) of silicon and a substantially higher “lowest unoccupied molecular orbital” (LUMO)/conduction-band edge (Ec) of the material than the conduction band edge (Ec) of the silicon.

“hole-blocking layer” as used herein is a material that allows the through transport of electrons and prevents the through transport of holes to and from silicon. This may be achieved with an approximate alignment of LUMO/conduction-band edge (Ec) of the material with the conduction-band edge (Ec) of silicon, and a substantially lower HOMO/valence-band edge (Ev) of the material than the valence-band edge of the silicon (Ev).

“Surface passivation” as used herein is the removal of electrically active midgap defects on the surface of a semiconductor.

“Low-temperatures” as used herein are temperatures below about 500° C., and more preferably below about 160° C.

Disclosed is a new process for making solar cells, and for fabricating flexible electronics in general. The process is a low cost and high throughput technique for making solar cells that can be done at room temperature and in air ambient. As such, it has considerable cost and speed advantages over conventional solar cell fabrication techniques, which use high temperature processes with ultrapure gases in a well-controlled cleanroom environment. The process is designed to be a low-cost and high throughput process for making commercial solar cells. It will offer considerable cost and speed advantages over existing technologies.

Disclosed herein are low-cost high-efficiency photovoltaic (PV) devices including inorganic/organic, e.g., silicon/organic heterojunctions (SOH). In SOH cells, the light is absorbed in silicon just like conventional crystalline/multi-crystalline silicon PV, but there is no p-n junction. Instead, the carriers are separated by the field created by silicon/organic heterojunction, e.g., a thin layer of an organic semiconductor on silicon. This low-cost room-temperature process obviates the need for any expensive high-temperature diffusion steps required to fabricate p-n junctions. Furthermore, unlike dopant-diffusion, organics can be deposited by high-throughput process, such as spin-coating, spray-coating or lamination, which are very scalable. Together these advantages translate can into substantial cost savings while maintaining high efficiencies.

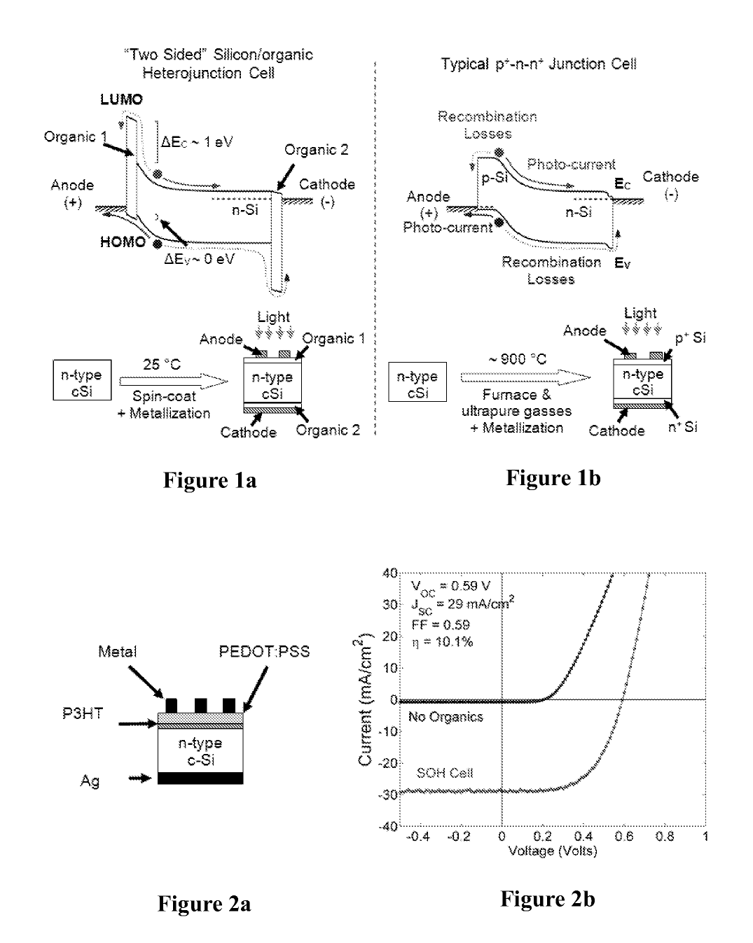

FIGS. 1a and 1b are block diagrams comparing a Si/organic heterojunction and a conventional p-n-n+ junction. In FIG. 1a, the large LUMO/EC offset at the anode blocks electrons but collects holes, replacing p-n junction, and the large HOMO/EV offset at the cathode blocks holes but collects electrons, replacing the back-surface field.

The organic in an SOH cell is a wide energy-gap organic semiconductor that functions either as an electron- or a hole-blocking layer. The energy levels of “Organic 1” are designed such that the HOMO is aligned with the Si valence-band edge (EV), allowing collection of photogenerated holes at the anode, but the LUMO is much higher than the conduction-band edge (EC) of Si, preventing electrons from recombining at the anode. “Organic 1” layers can be thought of as the replacement for p-n junction of the conventional cell (FIG. 1b). “Organic 2” allows collection of photo-generated electrons but blocks hole recombination at the cathode, replacing the conventional n/n+ back-surface field. Together, the electron and hole-blocking layers reduce dark-current of the device and yield a high VOC under illumination.

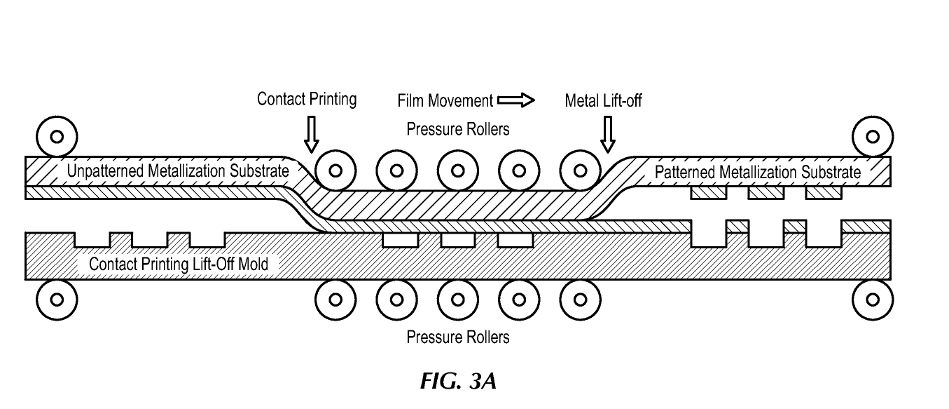

FIG. 2a shows the structure of a Si/P3HT heterojunction solar cell. FIG. 2b shows the current-voltage characteristic of our “one-sided” Si/organic heterojunction solar cell (lower curve) compared to a device without PEDOT/P3HT stack (upper curve) under AM1.5 illumination. The active area of device is 4 mm×4 mm. The device uses P3HT as an electron blocker (“organic 1” only, no backside “organic 2”) with an open-circuit voltage of 0.59 V and power-efficiency of 10.1% under AM1.5 illumination.

SOH solar cells eliminate the need for high-temperature steps; hence they can be fabricated at room temperature in air by applying thin layers of organic semiconductor onto silicon. As such, the SOH structure has the potential to enable an ultra-low cost and highly scalable roll-to-roll (R2R) process. R2R fabrication methods can lead to significant cost savings in three distinct areas of photovoltaic (PV) devices: (i) Cell Processing: The SOH approach replaces high temperature diffusions and ultra-clean environments with near-room temperature processing and enables a low-cost method of anode metallization pattering, (ii) Module Assembly: eliminating expensive PV module structural components and materials such as glass and metal frames (−25% of module cost), and (iii) balance of system: module will be flexible with sub 50 μm Si wafers and can enable lower deployment and lower balance of system costs.

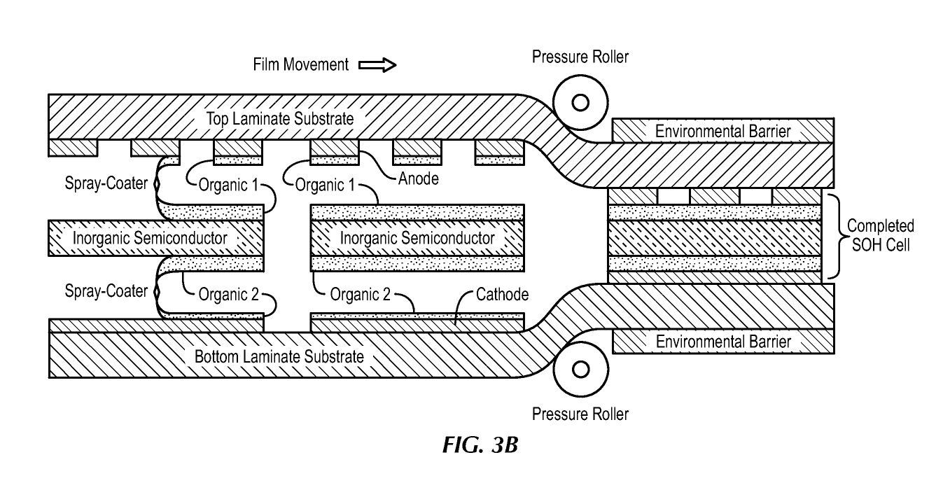

FIG. 3a is a block diagram showing a spray coating roll to roll process. The spray-coating based R2R fabrication process has 4 basic steps. First the top and bottom metallization films are formed by patterning the low-cost and commercially-available metal coated plastic films, e.g. Al coated PET. The patterning may be done by contacting printing and lift-off of the metal layer with a pre-patterned mold as shown. In this example only the top metallization film is shown. The same process may be used for the bottom metallization film.

FIG. 3b is a block diagram showing spray-coating of organic on the silicon wafer and metallization films, lamination of the three components to form the SOH cell, and encapsulation of the module with environmental barrier films. In more detail, SOHs are formed on the front and back of the silicon (single/multi-crystalline) wafer by spray-coating the appropriate organic layers. The corresponding organic layers are also spray-coated on the surface of the patterned electrodes to facilitate conformal and intimate contact during lamination. Next the three components are aligned and laminated together via pressure rollers to form the SOH solar cell. Finally a protective environmental barrier layer is deposited on the top and bottom surface of the laminated stack to prevent permeation (through the flexible substrates) of moisture, oxygen and other substances that can degrade cell performance. The completed solar cells may then be hermetically sealed between the top and bottom laminate substrates, e.g., using a standard EVA encapsulant (not shown). Suitable organic layers may include one or more of the following: Poly(3,4-ethylenedioxythiophene) (PEDOT) or poly(3-hexylthiophene) (P3HT). The typical pressure range for lamination is about 50-250 psi. The typical temperature range is about 0-200 C.

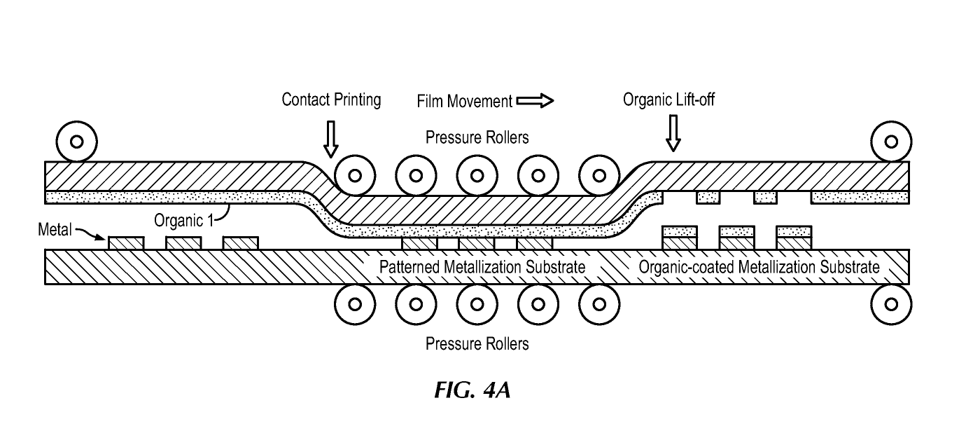

FIG. 4a is a block diagram showing lamination of organic coating on the surface of metallization film. In this example only the top metallization film is shown. The same process may be used for the bottom metallization film. In more detail, the lamination-based R2R fabrication process has 5 basic steps. Like the spray-coating based process, the top and bottom metallization films are first formed by patterning the low-cost and commercially-available metal coated plastic films. The patterning may also done by contact printing and lift-off of the metal layer with a pre-patterned mold as shown in FIG. 3a. Next organic layers are applied to the surface of the metallization films by lamination as shown in FIG. 4a. Next the SOHs are formed on the front and back of the silicon (single/multi-crystalline) wafer by laminating the appropriate organic layers as shown in FIG. 4b. Next the three components are aligned and laminated together via pressure rollers to form the SOH solar cell as shown in FIG. 4c. Finally protective environmental barrier layer are deposited on the top and bottom surface of the laminated stack to prevent permeation (through the flexible substrates) of moisture, oxygen and other substances that can degrade cell performance. The completed solar cells may then be hermetically sealed between the top and bottom laminate substrates using the standard EVA encapsulant (not shown). Note one “organicl” and one “organic 2” layer may be needed on the surface of the silicon wafer to form silicon/organic heterojunctions. Organic layers formed on the metallization may be provided for adhesion and bonding purpose. Such layers may be different organic material and are optional. The organic layers on the metallization films may be spray-coated before patterning of the metal. The layered structure (metal/organic) may be patterned in one step using the transfer or contact printing (lift-off process) as shown in FIG. 3. The environmental barrier may be deposited on the metallization foil prior to R2R processing. Suitable films may be purchased with the barrier layer pre-deposited.

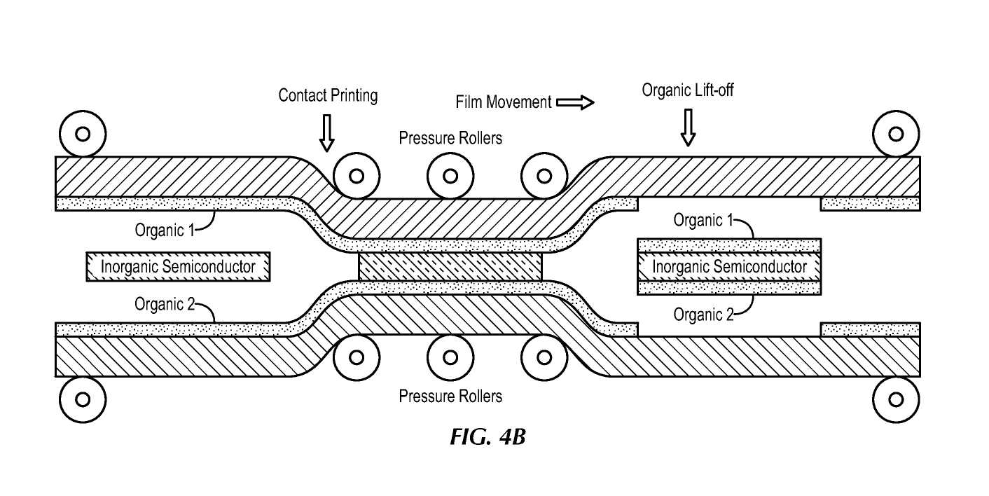

It should be understood that a variety of different layers or combinations of layers may be formed using the processes disclosed above. All of the examples below are formed with low temperature processes. It should be understood that the term lamination as used herein encompasses transfer printing where a backing layer removed after lamination. The examples below are directed to lamination processes but could incorporate one or more transfer printing operations to join the various layers without departing from the scope of this disclosure. The resulting structures are formed without the need for high temperate processing steps. In FIGS. 5-11 any backing layers have been omitted for purposes of clarity. FIG. 5a is a block diagram showing lamination of organic(s) on an inorganic semiconductor layer. In this example one or more organic layers 22 is laminated to inorganic semiconductor layer 24. The resulting structure incorporates a heterojuction formed between the inorganic semiconductor layer 24 and the organic layer 22.

FIG. 5b is a block diagram showing lamination of organic(s) on an organic coated inorganic semiconductor layer. In this example, one or more organic layers 32 are laminated to inorganic semiconductor layer 32. The inorganic semiconductor layer 32 is organic coated as shown by reference number 36. As discussed above, one of the organic layers may be used to form a heterojunction, another organic layer may be provided for adhesion and bonding purposes.

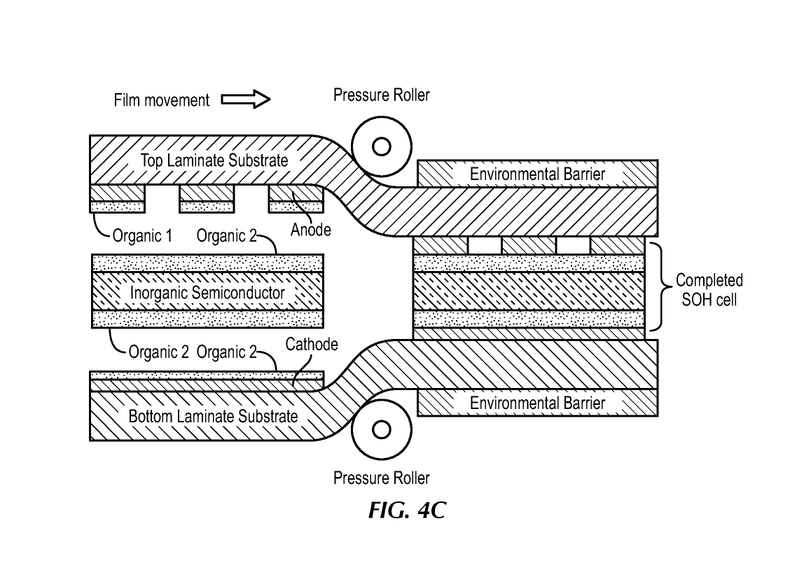

FIG. 6a is a block diagram showing lamination of a metal(s)/organic(s) stack on an inorganic semiconductor layer. In this example one or more metal layer 42 and one or more organic layers 46 are laminated to an inorganic semiconductor layer 44. The inorganic semiconductor layer 44 may be formed with a junction 49, e.g., a PN junction or a heterojunction. It should be understood that both layers in a heterojunction need not be doped. FIG. 6b is a block diagram showing lamination of a metal(s)/organic(s) stack on an organic(s)-coated inorganic semiconductor layer. In this example one or more metal layers 52 and one or more organic layers 58 are laminated to an organic coated (see reference number 56) inorganic semiconductor layer 54. The inorganic semiconductor layer 54 may be formed with a junction 59, e.g., a PN junction or a heterojunction. It should be understood that the inorganic semiconductor layers shown in the remaining figures may also be formed with a PN junction or a heterojunction as disclosed above.

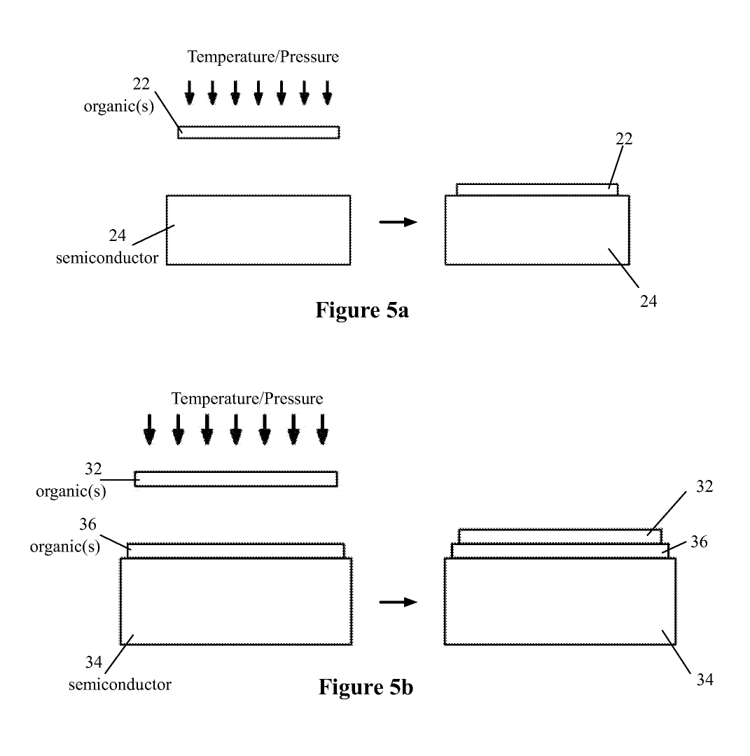

FIG. 7a is a block diagram showing lamination of a metal(s) on an inorganic semiconductor layer. In this example one or more metal layers 62 are laminated to inorganic semiconductor layer 64. FIG. 7b is a block diagram showing lamination of a metal(s) on an organic(s)-coated inorganic semiconductor layer. In this example one or more metal layers 72 are laminated to an organic coated (see reference number 76) inorganic semiconductor layer 74.

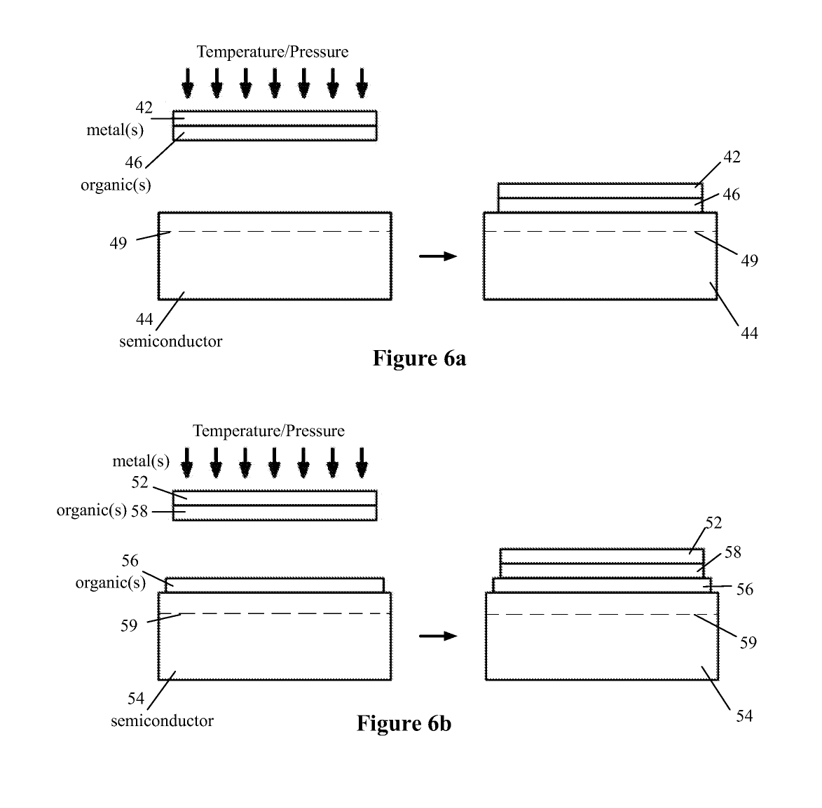

FIG. 8a is a block diagram showing lamination of metal(s) layers on solar cell, with a metal ledge or tab that extends outside device dimensions. In this example one or more metal layers 82 are laminated to an inorganic semiconductor layer 84. The metal layer is formed with a tab 88 that extends outside the dimensions of the inorganic semiconductor layer. Tab 88 may be used for subsequent connections and does not require a separate processing step for formation. FIG. 8b is a block diagram showing lamination of a metal(s)/organic(s) layer stack on solar cell, with a metal ledge that extends outside device dimensions. In this example one or more metal layers 92 and one or more organic layers 96 are laminated to an inorganic semiconductor layer 94. The metal layer is formed with a tab 98 that extends outside the dimensions of the inorganic semiconductor layer. As disclosed above, tab 98 may be used for subsequent connections and does not require a separate processing step for formation.

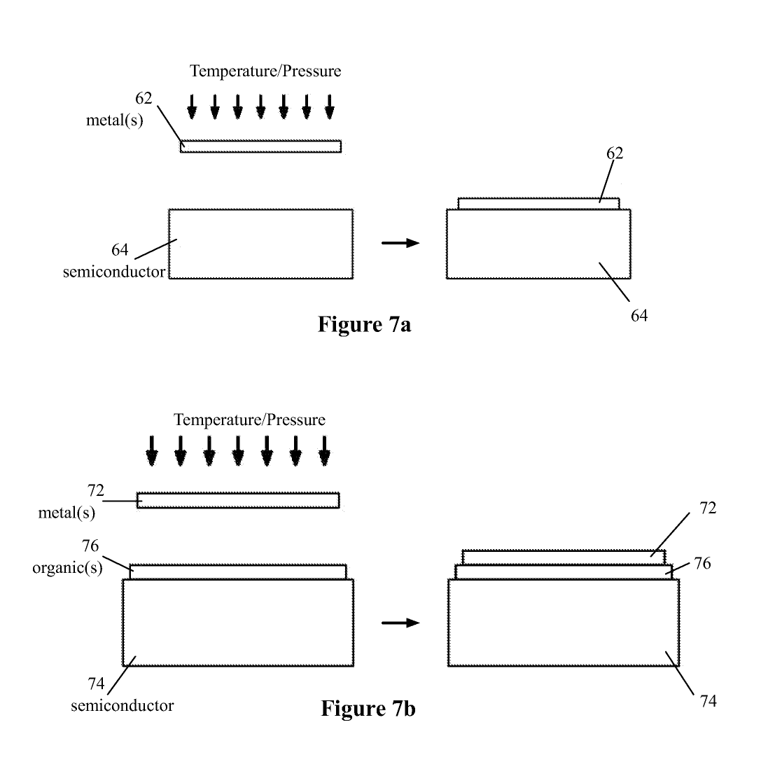

FIG. 9a is a block diagram showing lamination of two solar cells with metal ledges to form series connections. In this example one or more metal layers 102 are laminated to an inorganic semiconductor layer 104. The metal layer is formed with a tab 108 that extends outside the dimensions of the inorganic semiconductor layer. FIG. 9b is a block diagram showing the lamination of two solar cells with metal ledges to form series connections with an intermediate metal layer. After lamination, the two tabs 108 are coupled at joint 110. It should be understood that joint 110 may also include additional materials such as solder to adhesives to facilitate the connection between the two tabs 108.

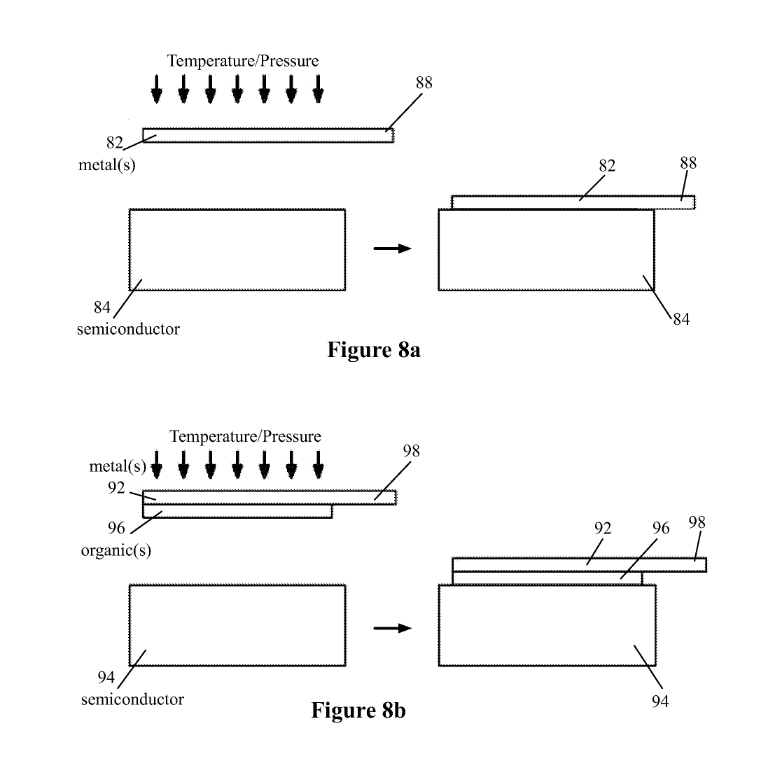

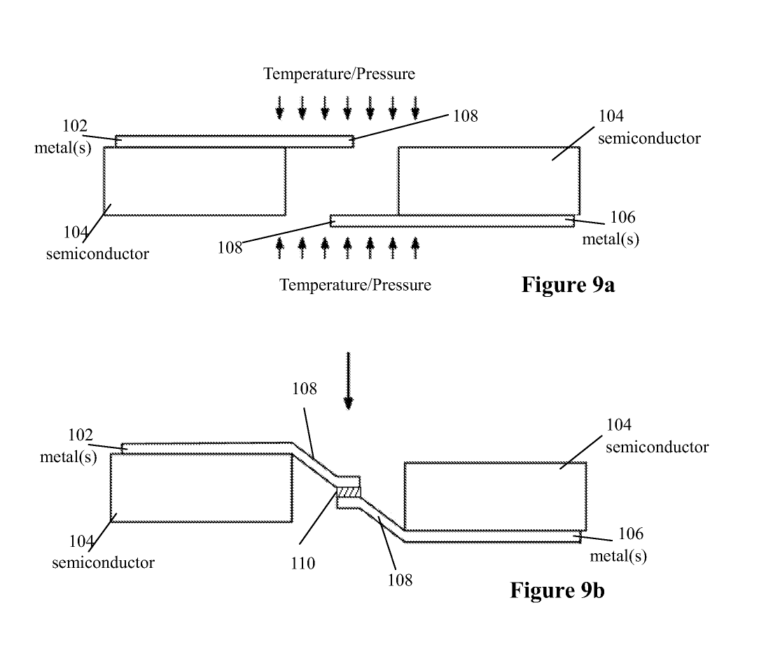

FIGS. 10a and 10b are block diagrams showing lamination of two solar cells with metal ledges to form parallel connections. In this example one or more metal layers 112 are laminated to inorganic semiconductor layers 124. This creates a parallel connection between the two cells as shown in FIG. 10b. It should be understood that the disclosed series and parallel connections may be combined in a single assembly to create a module having the desired voltage and current specifications. FIGS. 11a and 11b are block diagrams showing lamination of two solar cells with metal/organic layer to form parallel connections. In this example one or more metal/organic layers 132, 136 are laminated to inorganic semiconductor layers 134. This creates a parallel connection between the two cells as shown in FIG. 11b.

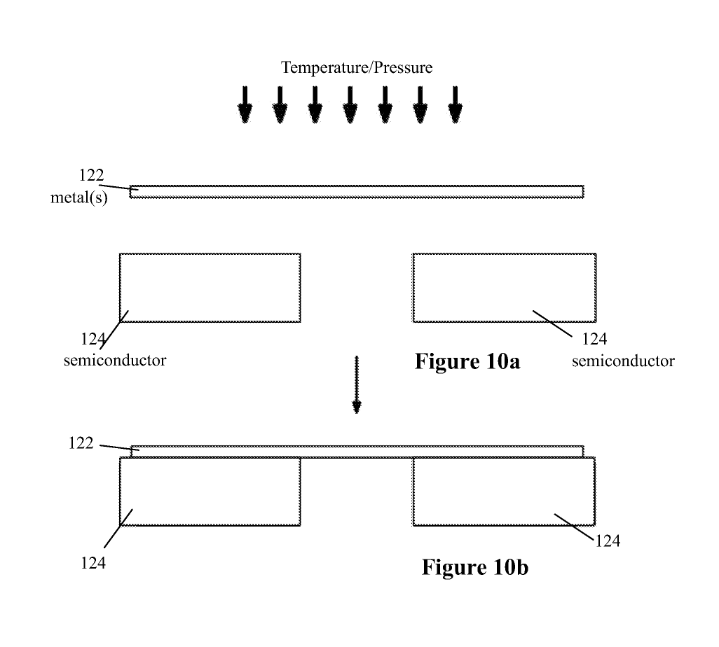

It should be understood that the embodiments disclosed above may be constructed using a variety of lamination techniques. FIGS. 12a-12c are block diagrams showing transfer printing of a layer using a removable backing layer. In this example one or more metal and/or organic layers 146 are laminated to inorganic semiconductor layers 144 via backing layer 142 as shown in FIGS. 12a and 12b. Once the lamination process is complete, the backing layer 142 may be removed as show in FIG. 12c.

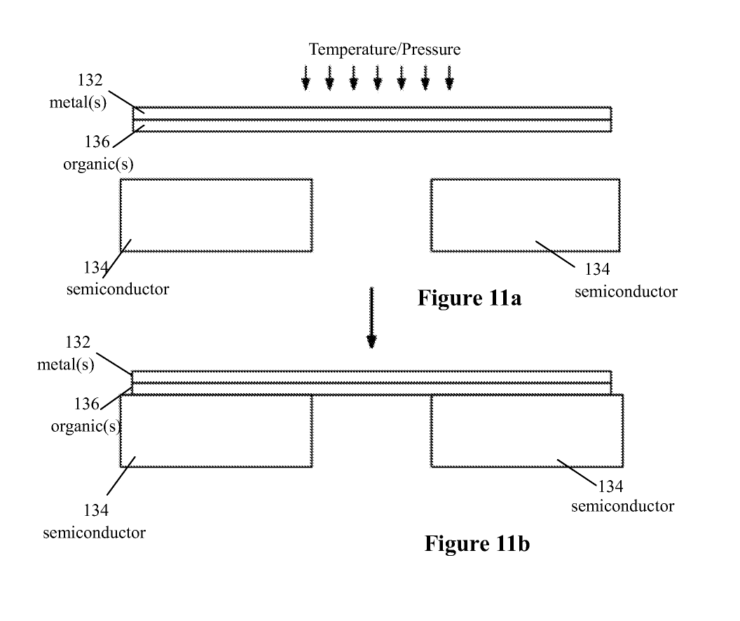

FIGS. 13a-13c are block diagrams showing transfer printing of a patterned metal/organic layer using a removable backing layer. In this example one or more patterned metal and/or organic layers 156 are laminated to inorganic semiconductor layers 154 via backing layer 152 as shown in FIGS. 13a and 13b. Once the lamination process is complete, the backing layer 152 may be removed as show in FIG. 13c. It should be understood that the patterned metal and/or organic layers 156 may be patterned using a variety of well-known patterning techniques.

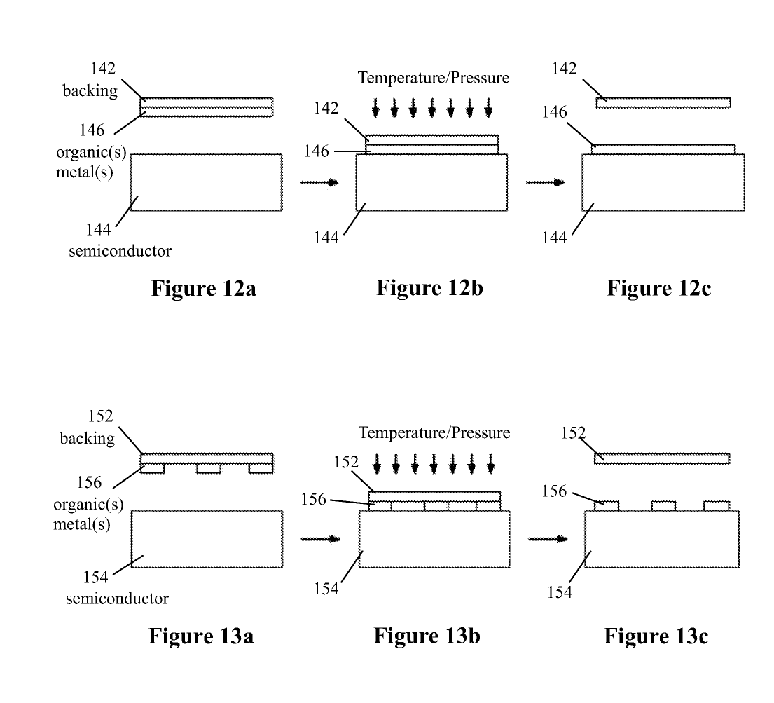

FIGS. 14a-14c are block diagrams showing transfer printing of a patterned metal/organic layer using a removable backing layer. In this example one or more patterned metal and/or organic layers are created during lamination the lamination process. Metal and/or organic layers 166 are laminated to inorganic semiconductor layers 164 via backing layer 162 as shown in FIGS. 14a and 14b. The metal and/or organic layers 166 are automatically patterned by application of local (non-uniform) pressure/temperature, e.g., using an appropriately patterned stamp (not shown). Once the lamination process is complete, the backing layer 162 may be removed yielding patterned metal and/or organic layers 167 as shown in FIG. 14c.

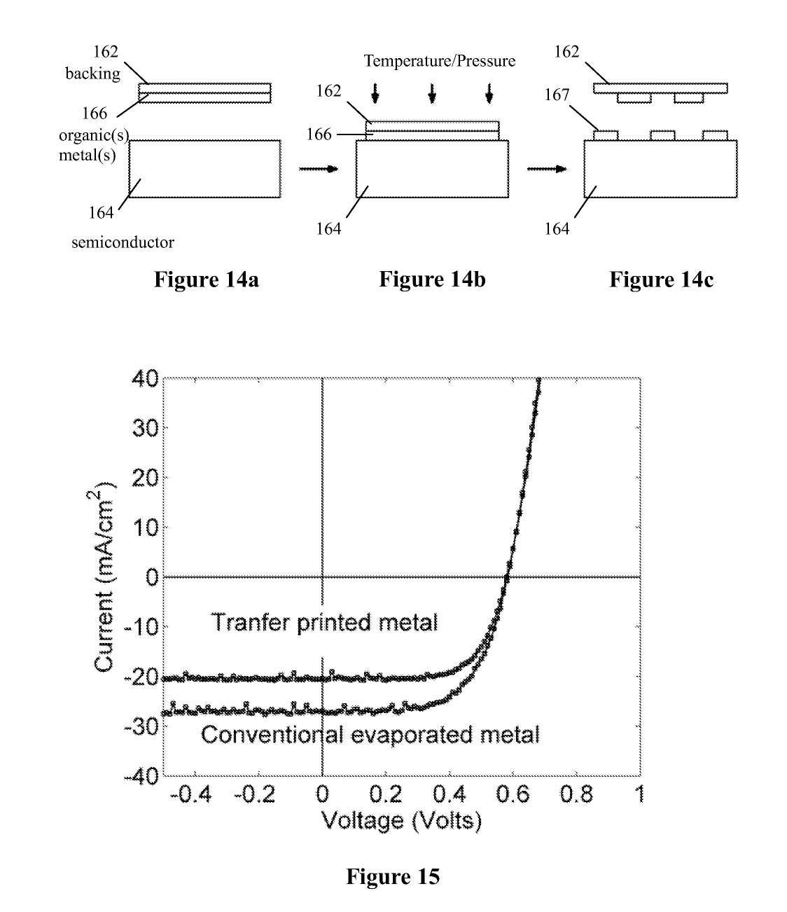

FIG. 15 is a graph showing experimental results from transfer printing of a metal layer (a conventionally fabricated evaporated solar cell is also shown for comparison). The transfer printing was generally carried out using the approach shown in FIGS. 12a-12c. In this example metal and/or organic layers 146 was a silver metal layer. Backing layer 142 was a silicone rubber backing layer. The silver metal layer was laminated to an organic coated inorganic semiconductor layer 144 via backing layer 142 as shown in FIGS. 12a and 12b. Once the lamination process was completed, the backing layer 142 was removed as show in FIG. 12c.

While the total cost of a silicon PV module has fallen sharply over the last decade, the cost of fabricating an individual cell has stayed relatively constant. This is because the basic building block of silicon solar cell, the diffused p-n junction, is still made at high-temperatures. Inorganic/organic, e.g., organic/Si heterojunctions offer a way to eliminate all these expensive steps, while maintaining high efficiencies. Traditional cell fabrication process is slow (requires tens of minutes for each step), but the disclosed R2R process based on lamination or spray-coating is much faster, substantially decreasing production time and hence costs of silicon solar cells. The R2R process allows the use of laminate substrate as part of the SOH solar cell packaging. Coupled with the environmental barrier, this can significantly reduce the costs of PV module assembly by eliminating glass, metal frames and many other expensive structural components. The R2R process coupled with ultra-thin silicon wafers will enable highly efficient flexible SOH PV modules that can significantly reduce the deployment and balance-of-system costs.

Although features and elements are described above in particular combinations, each feature or element may be used alone without the other features and elements or in various combinations with or without other features and elements.

What is claimed is:

1. A method of making a photovoltaic device, the method comprising:
laminating an organic layer onto an inorganic semiconductor layer; and
electrically coupling a first electrical contact to the organic layer and a second electrical contact to the inorganic semiconductor layer.

2. The method of claim 1 wherein the inorganic semiconductor layer further comprise a second organic layer.

3. The method of claim 1 wherein at least one of the organic layer and the inorganic semiconductor layer is patterned.

4. The method of claim 1 wherein at least one of the organic layer and the second organic layer form a heterojunction with the inorganic semiconductor layer.

5. The method of claim 1 wherein the organic layer further comprises a metal layer.

6. The method of claim 1 wherein the organic layer comprises at least one of Poly(3,4-ethylenedioxythiophene) (PEDOT) and poly(3-hexylthiophene) (P3HT).

7. The method of claim 5 wherein at least one of the organic layer, the inorganic semiconductor layer and the metal layer are patterned.

8. The method of claim 5 wherein the inorganic semiconductor layer further comprise a second organic layer.

9. The method of claim 5 wherein the metal layer comprises a first tab that overhangs at least one edge of the inorganic semiconductor layer.

10. The method of claim 8 further comprising:
providing a second photovoltaic device having a second metal layer including a second tab that overhangs at least one edge of a second inorganic semiconductor layer; and
electrically coupling the first tab to the second tab.

11. A method of making a photovoltaic device, the method comprising:
providing an inorganic semiconductor layer having at least one of a PN junction and a heterojunction; and
laminating a metal layer onto the inorganic semiconductor layer to form an electrical contact.

12. The method of claim 11 wherein the inorganic semiconductor layer further comprise an organic layer.

13. The method of claim 11 wherein the organic layer comprises at least one of Poly(3,4-ethylenedioxythiophene) (PEDOT) and poly(3-hexylthiophene) (P3HT).

14. The method of claim 11 wherein at least one of the inorganic semiconductor layer and the metal layer is patterned.

15. The method of claim 11 further comprising: providing a second inorganic semiconductor layer having at least one of a PN junction and a heterojunction, wherein the metal layer is laminated onto the first and second inorganic semiconductor layers to form the electrical contact.

16. The method of claim 11 wherein the metal layer comprises a first tab that overhangs at least one edge of the inorganic semiconductor layer.

17. The method of claim 16 further comprising:
providing a second photovoltaic device having a second metal layer including a second tab that overhangs at least one edge of a second inorganic semiconductor layer; and
electrically coupling the first tab to the second tab.

18. A photovoltaic device comprising:
an inorganic semiconductor layer having at least one of a PN junction and a heterojunction; and
a metal layer laminated to the inorganic semiconductor layer to form an electrical contact, the metal layer being formed with a first tab that overhangs at least one edge of the inorganic semiconductor layer.

19. The photovoltaic device of claim 18 wherein the inorganic semiconductor layer further comprise an organic layer.

20. The photovoltaic device of claim 18 wherein the organic layer comprises at least one of Poly(3,4-ethylenedioxythiophene) (PEDOT) and poly(3-hexylthiophene) (P3HT).

21. The photovoltaic device of claim 20 wherein at least one of the organic layer and the inorganic semiconductor layer is patterned.

22. The photovoltaic device of claim 18 further comprising a conductive compound disposed between the first tab and the second tab.

23. The photovoltaic device of claim 18 further comprising: a second photovoltaic device having a second metal layer including a second tab that overhangs at least one edge of a second inorganic semiconductor layer; and an electrical connection coupling the first tab to the second tab.

24. A photovoltaic device comprising, a
a first inorganic semiconductor layer having at least one of a first PN junction and a first heterojunction,
a second semiconductor layer having at least one of a second PN junction and a second heterojunction; and
a metal layer laminated to the first and second inorganic semiconductor layers to form an electrical contact.

25. The photovoltaic device of claim 24 wherein at least one of the first and second semiconductor layers further comprise an organic layer.

26. The photovoltaic device of claim 24 wherein the metal layer further comprises an organic layer.

27. The photovoltaic device of claim 25 wherein the organic layer comprises at least one of Poly(3,4-ethylenedioxythiophene) (PEDOT) and poly(3-hexylthiophene) (P3HT).

28. The photovoltaic device of claim 24 wherein at least one of the metal layer and the first and second inorganic semiconductor layers are patterned.
